(19) United States
(12) Patent Application Publication
(10) Pub. No.: US 2008/0122534 A1
(43) Pub. Date: May 29, 2008

(54) Amplifier Switching Output Stage With Low Distortion

(76) Inventor: Bruce Halcro Candy, Basket Range (AU)

Correspondence Address: NATH & ASSOCIATES, 112 South West Street, Alexandria, VA, 22314, US

(21) Appl. No.: 11/666,985

(22) PCT Filed: Nov. 2, 2005
(86) PCT No.: PCT/AU05/01682

§ 371 Date: Aug. 24, 2007

(30) Foreign Application Priority Data
Nov. 3, 2004 (AU) 2004906300

(51) Int. Cl. H03F 3/217

(52) U.S. Cl. 330/251

(57) ABSTRACT

A class-D audio amplifier switching output stage with reduced distortion including, application of damping to the power supply voltage nodes in the form for example of a low inductance damping snubber circuit including a first resistor in series with a second capacitor connected via a low inductance path between the power supplies connecting the output switching devices.

### TECHNICAL FIELD

This invention relates to lowering distortion in a switching amplifier output stage using a damping means.

### BACKGROUND ART

The following descriptions are provided to assist the reader to understand how the current inventor has proceeded to analyse circuits of which he is aware to assist the reader to understand the relevance of the circuit invention. However these references are not intended and do not of themselves provide any admission by the applicant that they are published as may be required for an assessment of novelty or obviousness or are common general knowledge according to the laws of and in any particular country in the world.

Many models of commercial class-D audio amplifiers are known which are also referred to as switched or switching amplifiers. Electronic imperfections in all class-D audio amplifiers cause increased inaccuracy or put in other terms, increased distortion.

Most class-D audio amplifier include negative feedback to reduce distortion but still mathematically intrinsically produce distortion even for idealised electronics. This intrinsic distortion is usually a bigger contributor to the overall distortion than that caused by electronic imperfections. However, some new class-D systems do not produce significant intrinsic distortion, such as that disclosed in PCT Application PCT/AU2004/000149. Electronic imperfections contribute far more distortion than intrinsic sources in class-D amplifiers using these methods. Thus it is desirable to reduce electronic distortions to take better advantage of these new systems.

An object of this invention is therefore to provide an amplifier improvement that assists in reducing distortion or at least provides the public with a useful alternative.

### SUMMARY OF INVENTION

In one form of this invention there is provided; a class-D audio amplifier switching output stage comprising, switching semiconductors, the said switching semiconductors connected to at least a first power supply node and a second power supply node, and a means for damping between the power supply nodes.

The said means for damping between the power supply nodes comprises a damping snubber circuit.

In a preferred embodiment of the invention there is provided; A class-D audio amplifier switching output stage comprising, switching semiconductors, at least a first power supply node and a second power supply node, at least a first capacitor connected between the first power supply node and the second power supply node, wherein a damping snubber circuit is connected between the first power supply node and the second power supply node, and further wherein the said damping snubber circuit includes at least a first resistor and a second capacitor.

In a further embodiment of the invention the total series inductance connecting at least one of the switching semiconductors, the first and second power supply nodes and the first resistor and second capacitor is less than 0.1 micro Henries.

The invention is further characterised in that a ringing voltage between the first and second power supply nodes when a voltage difference is applied between the first and second power supply nodes and the switching semiconductors are operating with the said damping snubber circuit disconnected is reduced at least by a factor of two when the damping snubber circuit is connected.

Power supply voltages supplying switching semiconductors in class-D amplifier switching output stages exhibit ringing voltage following switching transitions of the switching semiconductors when they are operating. This results from stray inductance of the printed circuit board and switching semiconductors and capacitance of various circuit components; mostly capacitance of the switching semiconductors. Low inductance decoupling capacitors, ground planes and general well designed printed circuit board track designs help in reducing this ringing. The inventor has discovered that this ringing modulates the output voltage and varies as the duty cycle varies and hence causes distortion.

The inventor has discovered that this source of distortion may be reduced by the application of damping to the power supply voltage nodes in the form for example of a low inductance damping snubber circuit including a first resistor in series with a second capacitor connected via a low inductance path between the power supplies connecting the output switching devices.

### BRIEF DESCRIPTION OF THE DRAWINGS

For a better understanding of this invention it will now be described with respect to the preferred embodiment which shall be described herein with 20 the assistance of drawings wherein;

FIG. 1 shows one embodiment of the invention in a circuit using a damping snubber circuit.

### DETAILED DESCRIPTION OF THE INVENTION

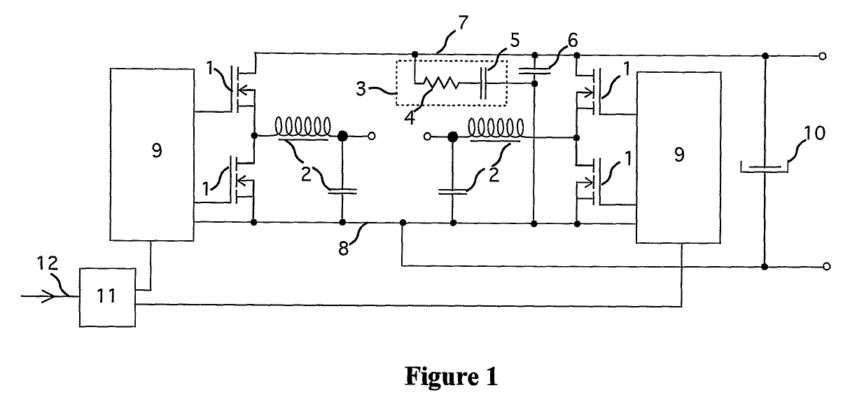

Referring to FIG. 1, a class-D audio amplifier input 12 is connected to processing electronics 11 which includes a pulse width modulator. Outputs of the processing electronics 11 feed pulse width modulated switching signals to output switching high and low side drivers 9. These output switching high and low side drivers 9 feed the control inputs of output switching semiconductors 1, in this example shown as N channel FETs. The output switching semiconductors are supplied by power from a first power supply nodes 8 and a second power supply node 7. A first capacitor 6 of low self-inductance is connected between the first and the second power nodes to act as a low impedance a.c. path. Capacitor 10 assists the first capacitor 6 in creating a low impedance a.c. path between the first and the second power nodes and acts as a storage capacitor too. A damping snubber circuit 3 is also connected between the first and the second power nodes to damp ringing. This damping snubber circuit consists of a second capacitor 5 connected in series with a first resistor 4. An output low pass filter 2, sometimes called a demodulation filter consists of inductors connected to the switching outputs of the output switching semiconductors, and capacitors connected between the amplifier outputs and the first power supply node 8.

Measurements on 400 W Lyrus class-D audio amplifiers made by Halcro utilising the methods disclosed in P.C.T. Application PCT/AU2004/000149 (with a first order servo-loop amplifier) and this invention show that the distortion increases by up to a factor of 3 if the damping snubber circuits are disconnected, when a 4 ohm resistive load was connected to the amplifier output. These 400 W Lyrus class-D audio amplifiers used two parallel damping snubber circuits, one connected by a low inductance path to one half of an “H-bridge” amplifier switching output stage and the other to the other half of the “H-bridge” amplifier switching output stage. This output stage also had additional supply decoupling capacitors connected across the power supply nodes. The stored energy of the ringing is dissipated faster than a factor of two with the said damping snubber circuit connected compared to the damping snubber circuit being disconnected.

Although the invention has been herein shown and described in what is conceived to be the most practical and preferred embodiment, it is recognised that departures can be made within the scope of the invention, which is not to be limited to the details described herein but is to be accorded the full scope of the appended claims so as to embrace any and all equivalent devices and apparatus.

1. A class-D audio amplifier switching output stage including, switching semiconductors, the said switching semiconductors connected to at least a first power supply node and a second power supply node, and a means for damping between the power supply nodes.

2. The class-D audio amplifier switching output stage as in claim 1 further characterised where the said means for damping between the power supply nodes may include a damping snubber circuit.

3. A class-D audio amplifier switching output stage including, including, switching semiconductors, at least a first power supply node and a second power supply node, at least a first capacitor connected between the first power supply node and the second power supply node, wherein a damping snubber circuit is connected between the first power supply node and the second power supply node, and further wherein the said damping snubber circuit includes at least a first resistor and a second capacitor.

4. The class-D audio amplifier switching output stage of claim 3 wherein the total series inductance connecting at least one of the switching semiconductors, the first and second power supply nodes and the first resistor and second capacitor is less than 0.1 micro Henries.

5. The class-D audio amplifier switching output stage of claim 3 wherein a ringing voltage between the first and second power supply nodes when a voltage difference is applied between the first and second power supply nodes and the switching semiconductors are operating and when said damping snubber circuit is disconnected is reduced at least by a factor of two when the damping snubber circuit is connected.
